(19) United States
(12) Patent Application Publication
(10) Pub. No.: US 2010/0027273 A1
(43) Pub. Date: Feb. 4, 2010

(54) COATINGS FOR REFLECTIVE SURFACES

(75) Inventor: Thomas E. Deacon, Cupertino, CA (US)

Correspondence Address: MURABITO, HAO & BARNES, LLP, TWO NORTH MARKET STREET, THIRD FLOOR, SAN JOSE, CA, 95113, US

(73) Assignee: EPICREW CORPORATION, Nagasaki (JP)

(21) Appl. No.: 12/182,078

(22) Filed: Jul. 29, 2008

(51) Int. Cl. F21V 7/00; H01L 21/00

(52) U.S. Cl. 362/341; 438/795; 257/E21.001

(57) ABSTRACT

Systems and methods of coatings for reflective surfaces. An optical system includes a reflective surface for reflecting optical energy and a transparent coating disposed upon the reflective surface. The coating may be characterized as more chemically inert than the reflective surface in an operating environment of the reflector. The coating may be characterized as harder than the reflective surface. The coating may be characterized as more refractory than the reflective surface. The coating may include diamond like carbon and/or other tetrahedrally bonded stable material, e.g., silicon carbide.

### FIELD OF INVENTION

Embodiments of the present invention relate to the field of optics. More specifically, embodiments of the present invention relate to systems and methods of coatings for reflective surfaces.

### BACKGROUND

Numerous industries and technologies utilize reflective surfaces. For example, the semiconductor industry widely utilizes reflective surfaces, or reflectors, to uniformly convey heat and/or light energy from a lamp to a semiconductor wafer, e.g., as used in the formation of epitaxial layers for semiconductors. For example, FIG. 1 (conventional art) illustrates a reflector system 100. Reflector system 100 comprises an energy source 110, e.g., a tubular tungsten halogen heating lamp, and a reflector structure 120, comprising a reflective surface 130. Reflective surface 130 is of a general parabolic shape and energy source 110 may be placed at the focus of the parabola. The reflector system 100 may be focusing or dispersing. In this manner, energy from the backside of the lamp is reflected off reflective surface 130 toward the intended object of the heating, e.g., a semiconductor wafer. Consequently, most of the output of the heating lamp is used for heating the target.

Another application of reflective surfaces is illustrated in FIG. 2 (conventional art). FIG. 2 illustrates a reflector assembly 200 as used in a solid state laser, e.g., a neodymium yttrium aluminum garnet (Nd:YAG) laser. A lasing medium (Nd:YAG) in the form of a cylindrical rod 210 and a linear flash lamp 220 are located inside a highly reflective elliptical chamber 230, comprising a reflecting surface 240. The flashlamp 220 is located along one focal axis of the ellipse and the laser rod 210 along the other focal axis of the ellipse. In this configuration, the properties of the elliptical reflector insure that most of the radiated energy from the flash lamp 220 passes through the laser rod 210, thereby providing efficient pumping.

The materials used in forming reflective surfaces 130 and 240 as well as other applications of reflective surfaces may be subject to high temperatures, corrosive chemical environments, mechanical wear due to forced air cooling, cleaning, polishing and handling, as well as other detrimental effects. Consequently, improvements in temperature and chemical resistance, improvements in mechanical wear characteristics as well as improvements in reflectivity are highly desired.

### SUMMARY OF THE INVENTION

Therefore, systems and methods of coatings for reflective surfaces are needed. In addition, systems and methods of coatings for reflective surfaces that provide increased hardness, improved scratch resistance and/or increased chemical inertness are needed. A further need exists for systems and methods of coatings for reflective surfaces with reduced maintenance requirements are needed. A still further need exists for systems and methods of coatings for reflective surfaces that are compatible and complimentary with existing systems and methods of semiconductor manufacturing are needed. Embodiments of the present invention provide these advantages and others as evident from the below description.

Accordingly, systems and methods of coatings for reflective surfaces are disclosed. An optical system includes a reflective surface for reflecting optical energy and a transparent coating disposed upon the reflective surface. The coating may be characterized as more chemically inert than the reflective surface in an operating environment of the reflector. The coating may be characterized as harder than the reflective surface. The coating may be characterized as more refractory than the reflective surface. The coating may include diamond like carbon and/or other tetrahedrally bonded stable material, e.g., silicon carbide and/or boron nitride.

In accordance with a method embodiment of the present invention, a method of processing a semiconductor substrate includes positioning a semiconductor substrate in an optical path with a light source and conveying energy from the light source to the semiconductor substrate via a direct optical path. Energy from the light source emitted in a non-direct path is reflected to the semiconductor substrate. The reflector includes a reflective surface and a transparent coating disposed thereon. The processing may further include growing an epitaxial layer on the substrate, wafer cleaning, etching, chemical vapor deposition, chemical mechanical polishing, sputtering, ion implantation, photo lithography, stripping and/or diffusion.

### BRIEF DESCRIPTION OF THE DRAWINGS

The accompanying drawings, which are incorporated in and form a part of this specification, illustrate embodiments of the invention and, together with the description, serve to explain the principles of the invention. Unless otherwise noted, the drawings are not drawn to scale.

FIG. 1 (conventional art) illustrates a reflector system as used in the formation of epitaxial layers for semiconductors.

FIG. 2 (conventional art) illustrates a reflector assembly as used in a solid state laser.

FIG. 3 illustrates a side sectional view of a portion of a reflective structure, in accordance with embodiments of the present invention.

FIG. 4 illustrates a reflective system, in accordance with embodiments of the present invention.

FIG. 5 illustrates a flowchart for an exemplary computer-controlled method of processing a semiconductor substrate, in accordance with embodiments of the present invention.

### DETAILED DESCRIPTION

Reference will now be made in detail to various embodiments of the invention, examples of which are illustrated in the accompanying drawings. While the invention will be described in conjunction with these embodiments, it is understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, it will be recognized by one of ordinary skill in the art that the invention may be practiced without these specific details. In other instances, well known methods, procedures, components, and circuits have not been described in detail as not to unnecessarily obscure aspects of the invention.

### Notation and Nomenclature

The terms “diamond-like” and “diamond-like carbon” are used by those of skill in the art and herein to refer to at least seven forms of amorphous carbon materials that display some of the unique properties of natural diamond.

### Coatings for Reflective Surfaces

While exemplary embodiments of the present invention may be illustrated with respect to the formation of epitaxial layer(s) on silicon wafers or substrates, it is appreciated that embodiments in accordance with the present invention are not limited to such exemplary devices and applications, and are well suited to many semiconductor manufacturing processes and semiconductor processing equipment types in addition to a variety of other optical reflecting applications. For example, embodiments in accordance with the present invention are well suited to a variety of optical and optical-like applications, including lasers, photo diode-based sensing devices, photomultiplier tubes, particle detectors, stepper imaging systems for use in photolithographic manufacturing, extreme ultraviolet (EUV) light sources and the like.

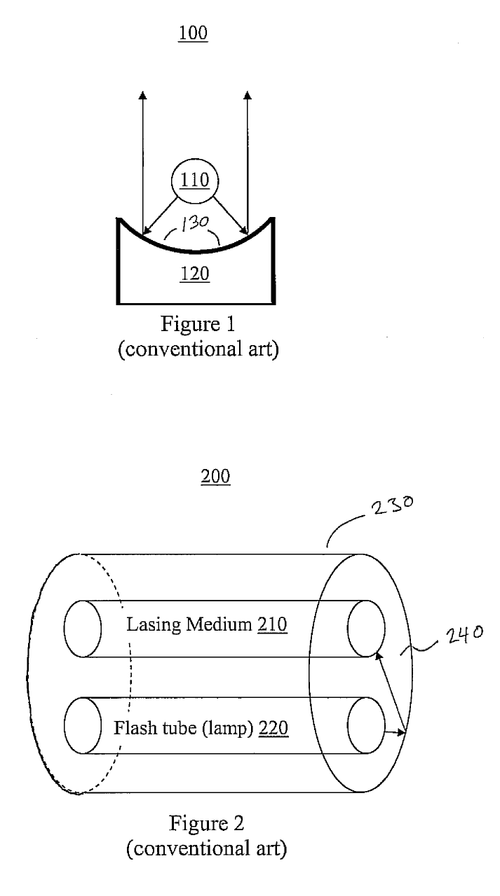

A reflector system, similar to reflector system 100 (FIG. 1) may be used to heat semiconductor substrates during chemical-vapor-deposition (CVD) processes or rapid thermal processing, including epitaxial reaction processes. Among other actions, a reflector system may operate to heat a wafer carrier or susceptor to very high levels, e.g., about 700° C.-1200° C. Likewise, the wafer being processed may also be heated, e.g., to similar temperatures.

In a semiconductor processing system, a heating lamp and reflector are generally not intentionally exposed to the highly corrosive gaseous environment of a CVD) processing chamber. However, high degrees of chemical inertness and hardness are desired of the reflector due to the presence of cooling water and/or forced air cooling, including debris and/or impurities in a cooling stream. For example, water leaks from system cooling water may spread spray or splatter on critical reflective surfaces, thus leaving deposits, foreign material or simply dirt on an otherwise highly polished reflective surface.

In addition, there exists a possibility of inadvertent exposure to processing chemicals, e.g., due to accidents and/or maintenance activities. Exemplary environments may comprise, for example, gas phase silicon sources, such as silicon tetrachloride (SiCl₄), trichlorosilane (SiHCl₃), dichlorosilane (SiH₂Cl₂) and/or silane (SiH₄) in a hydrogen carrier gas. In addition, reaction byproducts may be highly corrosive.

Further, agents utilized for periodic maintenance and cleaning of such processing chambers, e.g., nitric acid (HNO₃) and/or hydrofluoric acid (HF), and their byproducts, may be corrosive as well. Such cleaning or cleaning byproduct chemicals are likely to form detrimental contaminants as well. Still further, periodic maintenance, cleaning and polishing generally expose the processing equipment, including lamps and/or reflectors, to “normal” atmospheric air, water, dust and other agents, which alone or in concert with other agents may produce additional contaminants and/or may damage reflective surfaces.

The semiconductor industry widely utilizes a reflective surface, e.g., reflective surface 130 (FIG. 1), comprising gold. For example, reflective structure 120 may comprise a substructure of aluminum and/or aluminum nickel with a thin coating of gold, e.g., electroplated gold, forming the actual reflective surface 130. Such a gold surface has been determined to be an acceptable engineering compromise of good reflectivity and good heat tolerance combined with high chemical inertness.

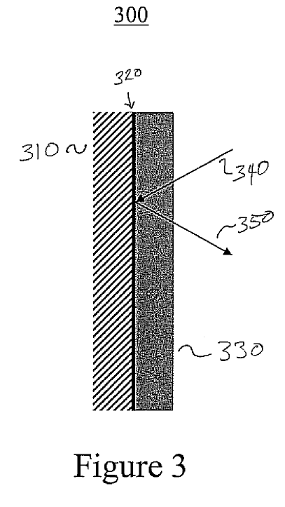

FIG. 3 illustrates a side sectional view of a portion of a reflective structure 800, in accordance with embodiments of the present invention. Reflective structure 300 comprises a base material or materials 310, a reflective material 320, e.g., gold, and a coating 330. It is appreciated that FIG. 3 is not drawn to scale, and that the illustrated dimensions of items 310, 320, 330 are not intended to reflect any actual dimensional relation among them. Incident light 340 and reflected light 350 illustrate the placement of coating 330 relative to base material 310, e.g., a light source is to the right of reflective structure 300, as illustrated.

Coating 330 may comprise diamond-like carbon, e.g., tetrahedral amorphous carbon, in accordance with embodiments of the present invention. Coating 330 may have a thickness in the range of about 5-50,000 angstroms. Coating 330 may be highly transparent, highly refractory (heat resistant), and highly resistant to chemicals. In addition, coating 330 should be highly resistant to mechanical wear.

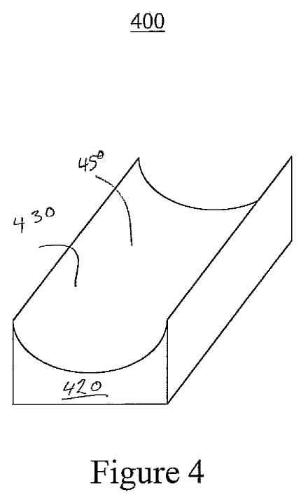

FIG. 4 illustrates a reflective system 400, in accordance with embodiments of the present invention. Reflective system 400 comprises a reflective structure 420 and a reflective surface 430. A coating 450, e.g., coating 330 (FIG. 3), is deposited over reflective surface 420. In one embodiment, reflective surface 430 comprises gold. In such an embodiment, coating 450 improves the mechanical wear characteristics of the relatively soft gold comprising reflective surface 430. Advantageously, the novel reflective structure comprising coating 450 is more durable, requires less maintenance and/or polishing, and may provide a longer service life with a more desirable reflection pattern, in comparison to the conventional art.

In accordance with alternative embodiments of the present invention, coating 450 may be deposited over a reflective surface 430 comprising materials) other than the conventional gold.

For example, silver has many attributes that are desirable for use as a reflective surface. Silver can be highly reflective, and is far less expensive than gold. However, silver is chemically reactive, and for this reason has generally not been suitable for use in many reflective applications, e.g., for heating wafer processing chambers.

However, in accordance with embodiments of the present invention, coating 330 (FIG. 3) may chemically passivate a layer of reflective material 320, e.g., silver, enabling a beneficial use of a variety of materials, including silver, in such reflective applications.

In addition to silver, coating 330 may enable use of a variety of other materials as a reflective surface 320. For example, aluminum is highly chemically reactive, e.g., forming aluminum oxide almost instantaneously in the presence of air. Such an oxide layer is generally deleterious to reflectivity. Consequently, under the conventional art, aluminum, while generally well suited for use as a base structure 310, is generally deemed unacceptable for use as a reflective surface 320.

In accordance with embodiments of the present invention, aluminum may be highly polished and coated with coating 330, e.g., in vacuo, producing a useful reflective surface 320. It is to be appreciated that coating 330 both passivates the aluminum reflective surface 320 as well as providing mechanical abrasion resistance. In this novel manner, aluminum, which is well suited to base structure 310, may also form reflective surface 320. For example, reflective surface 320 can be formed as a surface of base structure 310, without plating of another material. Accordingly, materials and production steps are advantageously eliminated in formation of a reflective structure 300.

In addition to the aforementioned materials, other materials generally considered undesirable for use as a reflective surface under the conventional art may be made desirable as reflective surfaces 320 by the addition of coating 330, in accordance with embodiments of the present invention. For example, many reflective materials may be too chemically active for various reflector applications. As previously discussed, silver and aluminum may be included in this category. In addition, reflective materials may be undesirably soft for various reflector applications, e.g., gold. Coating 320 beneficially improves both chemical inertness as well as hardness. Other materials that may form beneficial reflective surfaces 320 in combination with coating 330 include nickel, nickel chrome, nickel iron, rhodium, platinum rhodium, inconel (Ni, Fe, Cr) and the like.

In accordance with alternative embodiments of the present invention, coating 330 may comprise silicon carbide. Silicon carbide more readily forms a single stable crystalline phase, in contrast to carbon, which can form multiple structures, e.g., “diamond like” or “graphite like.” For mechanical and chemical durability, a “diamond like” crystal form may generally be preferred. However, the diamond like structure of carbon is not assured, but rather depends on a variety of deposition conditions, including, for example, source gas impurities, vacuum integrity, temperature and the like. It may be desirable to form a coating 320 comprising a stable compound of great durability, e.g., silicon carbide.

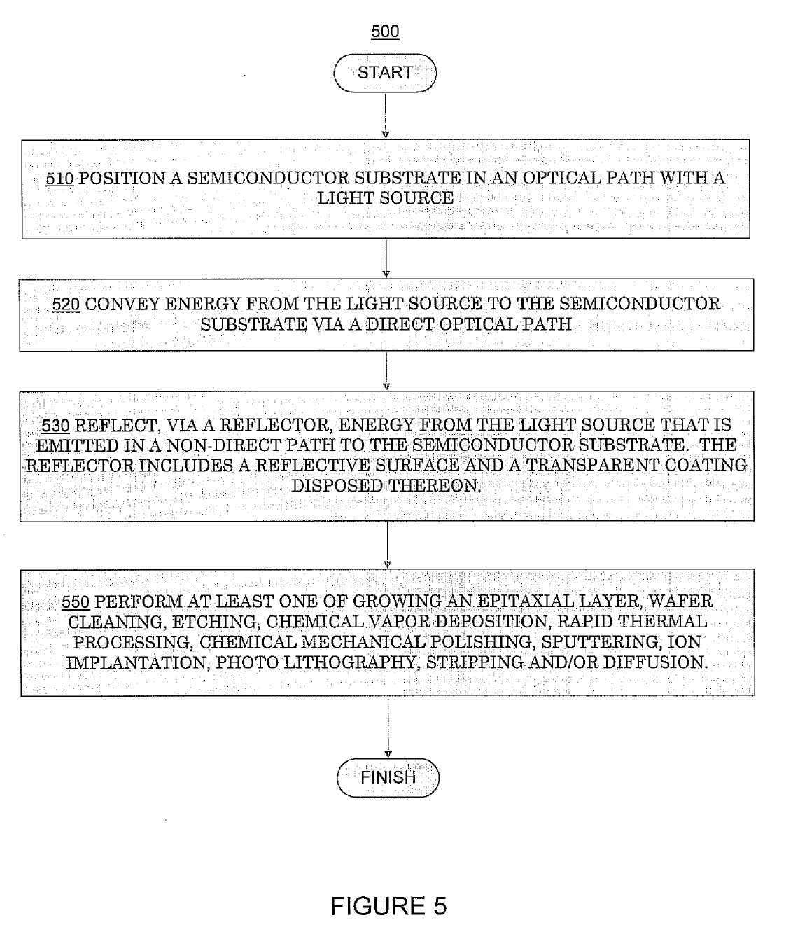

FIG. 5 illustrates a flowchart for an exemplary computer-controlled method 500 of processing a semiconductor substrate, in accordance with embodiments of the present invention. In 510, a semiconductor substrate is positioned in an optical path with a light source, e.g., a tungsten halogen heating lamp. In accordance with alternative embodiments of the present invention, exemplary light sources may also include extreme ultraviolet (EUV) light sources, including lasers, for example, KrF, ArF or F2 lasers, and other, non laser sources, e.g., as used for mask or reticle projection onto a wafer.

In 520, energy from the light source is conveyed to the semiconductor substrate via a direct optical path. In 530, energy from the light source emitted in a non-direct path to the semiconductor substrate is reflected by a reflector to the semiconductor substrate. The reflector comprises a reflective surface, e.g., reflective surface 320, 430, and a coating, e.g., coating 330, 450, disposed thereon, e.g., as shown in FIGS. 3 and 4.

In optional 540, a processing operation is performed on the semiconductor substrate. The processing may include growing an epitaxial layer, wafer cleaning, etching, chemical vapor deposition, rapid thermal processing, chemical mechanical polishing, sputtering, ion implantation, photo lithography, stripping and/or diffusion.

In accordance with embodiments of the present invention, the coating may comprise diamond like carbon. In accordance with alternative embodiments of the present invention, the coating may comprise silicon carbide. In another embodiment, the coating substantially comprises amorphous silicon carbide, e.g., silicon carbide characterized as having short range order in the solid film comprising a few molecular dimensions. It is further appreciated that embodiments in accordance with the present invention are well suited to coatings comprising other forms of silicon carbide.

In one embodiment, the thickness of the coating may range from about 5 to 50,000 angstroms. It is appreciated that embodiments in accordance with the present invention are well suited to other thickness of coatings as well.

In accordance with alternative embodiments of the present invention, coating 330 (FIG. 3) may comprise multiple layers of multiple materials. For example, coating 330 may comprise a first layer of silicon carbide, e.g., deposited on reflective surface 320, and a second layer of diamond like carbon, e.g., deposited on the first layer. Such a multi-layer coating may combine desirable characteristics of different materials. For example, silicon carbide may have improved adherence to some materials, in comparison to diamond like carbon. Diamond like carbon is generally harder than silicon carbide. Thus, an exemplary multi-layer coating may have improved adherence to a base material while providing a harder surface to the environment, in comparison to either material alone.

In addition, in accordance with alternative embodiments of the present invention, a multi-layer coating may have multiple indexes of refraction and multiple optical interfaces, which may be utilized to create or prevent internal reflections, e.g., reflections with the multiple layers. Further, a multi-layer coating may be utilized to filter selected wavelengths of light energy, for example, passing desirable wavelengths and rejecting unwanted wavelengths.

Embodiments in accordance with the present invention provide systems and methods of coatings for reflective surfaces. Embodiments in accordance with the present invention also provide for systems and methods of coatings for reflective surfaces that provide increased hardness, improved scratch resistance and/or increased chemical inertness. In addition, systems and methods of coatings for reflective surfaces with reduced maintenance requirements are provided. Further, embodiments in accordance with the present invention provide for systems and methods of coatings for reflective surfaces that are compatible and complimentary with existing systems and methods of semiconductor manufacturing.

Various embodiments of the invention are thus described. While the present invention has been described in particular embodiments, it should be appreciated that the invention should not be construed as limited by such embodiments, but rather construed according to the below claims.

What is claimed is:

1. A reflector for use in an optical system, comprising:
a reflective surface for reflecting optical energy; and
a transparent coating disposed upon said reflective surface.

2. The reflector of claim 1, wherein said coating is characterized as more chemically inert than said reflective surface in an operating environment of said reflector.

3. The reflector of claim 1, wherein said coating is characterized as harder than said reflective surface.

4. The reflector of claim 1, wherein said coating is characterized as more refractory than said reflective surface.

5. The reflector of claim 1, wherein said coating comprises diamond like carbon.

6. The reflector of claim 1, wherein said coating comprises silicon carbide.

7. The reflector of claim 1, wherein said coating comprises boron nitride.

8. The reflector of claim 1 wherein said coating comprises at least two layers, wherein each layer being of different materials from the set comprising diamond like carbon, silicon carbide and boron nitride.

9. The reflector of claim 1, wherein said coating comprises a thickness between about 5 and 50,000 angstroms.

10. An apparatus comprising:
a reflector for redirecting light energy from a heating lamp toward a semiconductor wafer, said reflector comprising:
a reflective surface for said redirecting; and
a transparent coating disposed upon said reflective surface for protecting said reflective surface.

11. The apparatus of claim 10 further comprising a chemical-vapor-deposition processing chamber for receiving light energy from said lamp redirected by said reflector.

12. The apparatus of claim 10 wherein said coating comprises diamond like carbon.

13. The apparatus of claim 10 wherein said coating comprises silicon carbide.

14. The apparatus of claim 10 wherein said reflective surface comprises gold.

15. The apparatus of claim 10 wherein said reflective surface does not comprise gold.

16. The apparatus of claim 10 wherein said reflective surface comprises one or more of the materials from the set comprising: silver; aluminum; nickel; nickel chrome; nickel iron; rhodium; platinum; and inconel (Ni, Fe, Cr).

17. A method of processing a semiconductor substrate, said method comprising:
positioning a semiconductor substrate in an optical path with a light source;
conveying energy from said light source to said semiconductor substrate via a direct optical path; and
reflecting, via a reflector, energy from said light source, emitted in a non-direct path, to said semiconductor substrate, wherein said reflector comprises a reflective surface and a transparent coating disposed thereon.

18. The method of claim 17 further comprising at least one of: growing an epitaxial layer; wafer cleaning; etching; chemical vapor deposition; rapid thermal processing; chemical mechanical polishing; sputtering; ion implantation; photo lithography; stripping; and diffusion.

19. The method of claim 17 wherein said coating comprises diamond like carbon.

20. The method of claim 17 wherein said coating comprises silicon carbide.

21. The method of claim 17 wherein said reflective surface comprises gold.

22. The method of claim 17 wherein said reflective surface comprises one or more of the materials from the set comprising: silver; aluminum; nickel; nickel chrome; nickel iron; rhodium; platinum; and inconel (Ni, Fe, Cr).
